(19) United States
(12) Patent Application Publication
(10) Pub. No.: US 2025/0351525 A1
(43) Pub. Date: Nov. 13, 2025

(54) HIGH ELECTRON MOBILITY TRANSISTOR AND METHOD FOR MANUFACTURING HIGH ELECTRON MOBILITY TRANSISTOR

(71) Applicant: SUMITOMO ELECTRIC INDUSTRIES, LTD., Osaka (JP)

(72) Inventor: Takahide HIRASAKI, Osaka (JP)

(21) Appl. No.: 19/191,428

(22) Filed: Apr. 28, 2025

(30) Foreign Application Priority Data
May 9, 2024 (JP) 2024-076228

(51) Int. Cl. H10D 64/64; H10D 30/01; H10D 30/47; H10D 62/85; H10D 64/01

(52) U.S. Cl. CPC H10D 64/64; H10D 30/015; H10D 30/475; H10D 62/8503; H10D 64/01

(57) ABSTRACT

A high electron mobility transistor includes a substrate, a semiconductor stacked body provided on the substrate, and a gate electrode in Schottky contact with the semiconductor stacked body. The gate electrode includes a first metal layer in direct contact with the semiconductor stacked body, and a second metal layer covering the first metal layer. The first metal layer contains at least one selected from the group consisting of cobalt in an amorphous state and ruthenium in an amorphous state.

### CROSS-REFERENCE TO RELATED APPLICATIONS

This application claims priority to Japanese Patent Application No. 2024-076228, filed May 9, 2024, the entire content of which is incorporated herein by reference.

### TECHNICAL FIELD

The present disclosure relates to a high electron mobility transistor and a method for manufacturing a high electron mobility transistor.

### BACKGROUND

As gate electrodes of high electron mobility transistors (HEMTs), a stacked film of a nickel layer, a platinum layer, and a gold layer has been proposed (Japanese Unexamined Patent Application Publication No. 2019-145605 (hereinafter “Patent Document 1”) and Japanese Unexamined Patent Application Publication No. 2021-044357 (hereinafter “Patent Document 2”)).

Although the techniques described in Patent Documents 1 and 2 achieve the intended object, there has been an increasing demand for further reduction of gate leakage in recent years.

### SUMMARY

A high electron mobility transistor according to the present disclosure includes a substrate, a semiconductor stacked body provided on the substrate, and a gate electrode in Schottky contact with the semiconductor stacked body. The gate electrode includes a first metal layer in direct contact with the semiconductor stacked body, and a second metal layer covering the first metal layer. The first metal layer contains at least one selected from the group consisting of cobalt in an amorphous state and ruthenium in an amorphous state.

### BRIEF DESCRIPTION OF THE DRAWINGS

FIG. 1 is a cross-sectional view illustrating a high electron mobility transistor according to a first embodiment.

FIG. 2 is a first cross-sectional view illustrating a method for manufacturing the high electron mobility transistor according to the first embodiment.

FIG. 3 is a second cross-sectional view illustrating a method for manufacturing the high electron mobility transistor according to the first embodiment.

FIG. 4 is a third cross-sectional view illustrating a method for manufacturing the high electron mobility transistor according to the first embodiment.

FIG. 5 is a first cross-sectional view illustrating a method of forming a gate electrode.

FIG. 6 is a second cross-sectional view illustrating the method of forming the gate electrode.

FIG. 7 is a third cross-sectional view illustrating the method of forming the gate electrode.

FIG. 8 is a diagram illustrating an example of a change in temperature when the gate electrode is formed.

FIG. 9 is a diagram illustrating another example of a change in temperature when the gate electrode is formed.

FIG. 10 is a cross-sectional view illustrating a high electron mobility transistor according to a second embodiment.

FIG. 11 is a first image of electron diffraction.

FIG. 12 is a second image of electron diffraction.

FIG. 13 is a third image of electron diffraction.

### DETAILED DESCRIPTION

It is desirable to provide a high electron mobility transistor capable of reducing gate leakage and a method for manufacturing such a high electron mobility transistor.

According to the present disclosure, gate leakage can be reduced.

### DESCRIPTION OF EMBODIMENTS OF PRESENT DISCLOSURE

First, aspects of the present disclosure will be listed and described.

<1> A high electron mobility transistor according to an aspect of the present disclosure includes a substrate, a semiconductor stacked body provided on the substrate, a gate electrode in Schottky contact with the semiconductor stacked body, the gate electrode including a first metal layer in direct contact with the semiconductor stacked body and a second metal layer covering the first metal layer, wherein the first metal layer contains at least one selected from the group consisting of cobalt in an amorphous state and ruthenium in an amorphous state.

The gate electrode contains at least one selected from the group consisting of cobalt in an amorphous state and ruthenium in an amorphous state as the first metal layer. Such a first metal layer can make gate leakage difficult to occur. Therefore, gate leakage can be reduced.

<2> In Aspect <1>, an electrical resistance of the second metal layer is lower than an electrical resistance of the first metal layer. In this case, the electric resistance of the gate electrode can be easily suppressed to be low.

<3> In Aspect <1> or <2>, the first metal layer may contain a hydrogen atom, a carbon atom, a nitrogen atom, and an oxygen atom. In this case, the first metal layer can be easily made amorphous.

<4> In any one of Aspects <1> to <3>, the second metal layer may contain at least one selected from the group consisting of gold, copper, and aluminum. In this case, the electrical resistance of the second metal layer can be suppressed to be low.

<5> In any one of Aspects <1> to <4>, the thickness of the first metal layer may be 3 nm or more and 50 nm or less. In this case, gate leakage can be easily reduced while the electric resistance of the gate electrode is suppressed to be low.

<6> In any one of Aspects <1> to <5>, the gate electrode may include a third metal layer between the first metal layer and the second metal layer. In this case, good adhesion is obtained between the first metal layer and the second metal layer.

<7> In Aspect <6>, the third metal layer may contain titanium. In this case, good adhesion can be easily obtained between the first metal layer and the second metal layer.

<8> In any one of Aspects <1> to <7>, the semiconductor stacked body may include a channel layer and a barrier layer between the channel layer and the gate electrode, and the gate electrode may be in direct contact with the barrier layer. In this case, the channel layer and the barrier layer can easily have excellent crystallinity.

<9> In any one of Aspects <1> to <7>, the semiconductor stacked body may include a channel layer, a barrier layer between the channel layer and the gate electrode, and a cap layer between the barrier layer and the gate electrode, and the gate electrode may be in direct contact with the cap layer. In this case, the channel layer, the barrier layer, and the cap layer can easily have excellent crystallinity, and electron traps can be easily reduced.

<10> In any one of Aspects <1> to <7>, the semiconductor stacked body may include a barrier layer and a channel layer between the barrier layer and the gate electrode, and the gate electrode may be in direct contact with the channel layer. In this case, the contact resistance between the source electrode and the drain electrode and the semiconductor stacked body can be easily suppressed to be low.

<11> In any one of Aspects <1> to <7>, the semiconductor stacked body may include a barrier layer, a channel layer between the barrier layer and the gate electrode, and a cap layer between the channel layer and the gate electrode, and the gate electrode may be in direct contact with the cap layer. In this case, the contact resistance between the source electrode and the drain electrode and the semiconductor stacked body is easily suppressed to be low, and electron traps can be easily reduced.

<12> In any one of Aspects <1> to <11>, the semiconductor device may further include an insulating film covering the semiconductor stacked body, an opening may be formed in the insulating film, and the gate electrode may be in Schottky contact with the semiconductor stacked body through the opening. In this case, the semiconductor stacked body can be protected by the insulating film.

<13> A method of manufacturing a high electron mobility transistor includes forming a semiconductor stacked body on a substrate and forming a gate electrode in Schottky contact with the semiconductor stacked body, and the forming of the gate electrode includes forming a first metal layer in direct contact with the semiconductor stacked body by atomic layer deposition and forming a second metal layer covering the first metal layer, wherein the first metal layer contains at least one selected from the group consisting of cobalt in an amorphous state and ruthenium in an amorphous state.

Since the first metal layer containing at least one selected from the group consisting of cobalt and ruthenium is formed by atomic layer deposition, the first metal layer can be easily made amorphous. Such a first metal layer can make gate leakage difficult to occur. Therefore, gate leakage can be reduced.

<14> In Aspect <13>, a source material of the first metal layer may contain at least one selected from the group consisting of bis(diisopropylbutaneamidinate) cobalt and bis(diisopropylbutaneamidinate) ruthenium. In this case, the first metal layer in an amorphous state can be easily formed.

<15> In the method according to Aspect <14>, in the forming of the first metal layer, at least one selected from the group consisting of hydrogen gas and ammonia gas may be supplied into a furnace together with the source material. In this case, the first metal layer in an amorphous state can be particularly easily formed.

<16> In any one of Aspects <13> to <15>, forming the gate electrode may include performing, before forming the first metal layer, a reduction treatment at a first temperature at which a natural oxide film on a surface of the semiconductor stacked body is decomposed, and the first metal layer may be formed at a second temperature lower than the first temperature. In this case, good Schottky characteristics can be easily obtained between the gate electrode and the semiconductor stacked body.

<17> In the method of Aspect <16>, performing the reduction treatment and forming the first metal layer may be performed in the same furnace without being opened to the atmosphere. In this case, particularly excellent cleanliness can be easily obtained on the surface of the semiconductor layered body.

<18> In the method of Aspect <17>, performing the reduction treatment and forming the first metal layer may be performed in respective furnaces without being exposed to the atmosphere. In this case, the temperature in the furnace in which the reduction treatment is performed and the temperature in the furnace in which the first metal layer is formed are controlled independently of each other, and thus a high throughput can be easily obtained.

<19> In any one of Aspects <16> to <18>, hydrogen gas and ammonia gas may be used in the reduction treatment. In this case, oxygen atoms are removed from the natural oxide film by hydrogen gas, and nitrogen deficiency of the semiconductor stacked body is compensated by ammonia gas.

### Details of Embodiments of Present Disclosure

Hereinafter, embodiments of the present disclosure will be described in detail, but the present disclosure is not limited thereto. In the present specification and the drawings, components having substantially the same functional configuration are denoted by the same reference numerals, and redundant description thereof may be omitted.

### First Embodiment

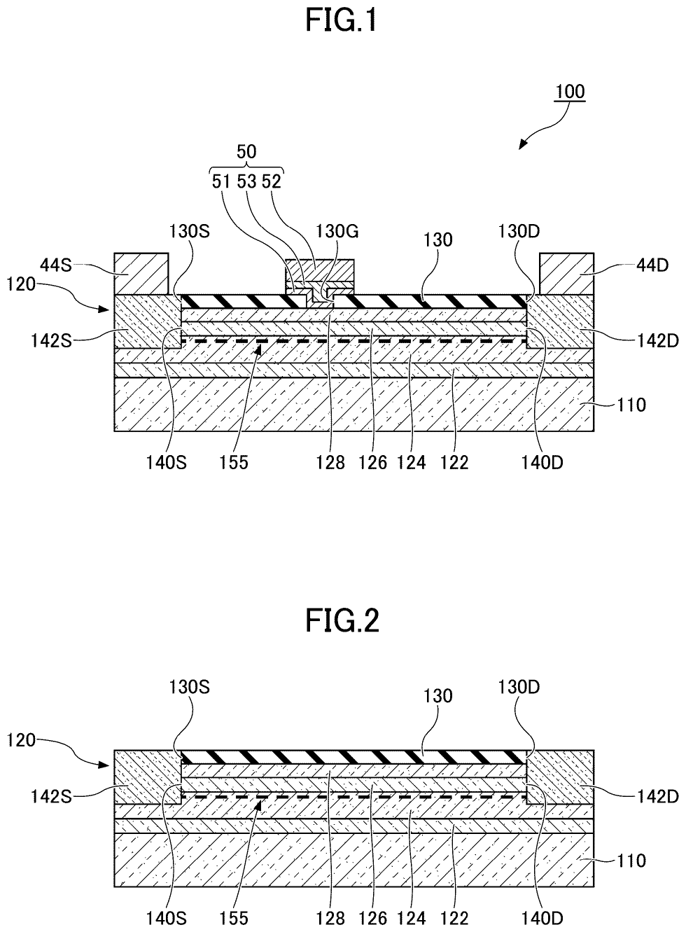

A first embodiment is described. The first embodiment relates to a high electron mobility transistor (HEMT). FIG. 1 is a cross-sectional view illustrating a high electron mobility transistor according to the first embodiment.

A high electron mobility transistor 100 according to the first embodiment includes a substrate 110, a semiconductor stacked body 120, an insulating film 130, a gate electrode 50, a source electrode 44S, and a drain electrode 44D, as illustrated in FIG. 1.

The substrate 110 is, for example, a substrate for growing a gallium nitride (GaN)-based semiconductor layer, and is, for example, a semi-insulating silicon carbide (SiC) substrate. In the case where the substrate 110 is a SiC substrate, the upper surface of the substrate 110 is a silicon (Si) polar plane. In the case where the surface of the substrate 110 is a Si polar plane, the semiconductor stacked body 120 is crystal-grown using a gallium (Ga) polar plane as a growth plane.

The semiconductor stacked body 120 includes a buffer layer 122, a channel layer 124, a barrier layer 126, a cap layer 128, a regrowth layer 142S, and a regrowth layer 142D.

The buffer layer 122 is on the substrate 110. The buffer layer 122 is, for example, an aluminum nitride (AlN) layer. The buffer layer 122 may include an AlN layer and a GaN layer or an aluminum gallium nitride (AlGaN) layer on the AlN layer. The channel layer 124 is on the buffer layer 122. The channel layer 124 is, for example, an undoped gallium nitride (GaN) layer. The barrier layer 126 is on the channel layer 124. The barrier layer 126 is, for example, an n-type AlGaN layer. A two-dimensional gas (2DEG) 155 exists near the upper surface of the channel layer 124. The cap layer 128 is on the barrier layer 126. The cap layer 128 is, for example, an n-type GaN layer.

A recess 140S for a source and a recess 140D for a drain are formed in the cap layer 128, the barrier layer 126, and a part of the channel layer 124. The recess 140S and the recess 140D penetrate the cap layer 128 and the barrier layer 126, and enter the channel layer 124. The channel layer 124 is exposed from the recess 140S and the recess 140D.

The insulating film 130 is on the cap layer 128. The insulating film 130 is, for example, a silicon nitride (SiN) film. The thickness of the insulating film 130 is, for example, 1 nm or greater and 10 nm or less. An opening 130S for a source and an opening 130D for a drain are formed in the insulating film 130. The opening 130S connects to the recess 140S, and the opening 130D connects to the recess 140D.

The regrowth layer 142S is on the channel layer 124 in the recess 140S and the opening 130S. The regrowth layer 142D is on the channel layer 124 in the recess 140D and the opening 130D. The regrowth layers 142S and 142D are, for example, an n-type GaN layer. The electrical resistances of the regrowth layers 142S and 142D are lower than the electrical resistance of the channel layer 124.

The source electrode 44S is on the regrowth layer 142S, and the drain electrode 44D is on the regrowth layer 142D. The source electrode 44S is in direct contact with the regrowth layer 142S, and the drain electrode 44D is in direct contact with the regrowth layer 142D. The source electrode 44S is in ohmic contact with the regrowth layer 142S, and the drain electrode 44D is in ohmic contact with the regrowth layer 142D.

An opening 130G for a gate is formed in the insulating film 130. The opening 130G is between the opening 130S and the opening 130D. The gate electrode 50 is provided on the insulating film 130 and is in Schottky contact with the semiconductor stacked body 120 through the opening 130G.

The gate electrode 50 includes a first metal layer 51, a second metal layer 52, and a third metal layer 53. The first metal layer 51 is in direct contact with the semiconductor stacked body 120. The second metal layer 52 covers the first metal layer 51. The third metal layer 53 is between the first metal layer 51 and the second metal layer 52. The first metal layer 51 is, for example, a cobalt (Co) layer in an amorphous state. The thickness of the first metal layer 51 is 3 nm or greater and 50 nm or less. The electrical resistance of the second metal layer 52 is lower than the electrical resistance of the first metal layer 51. The second metal layer is, for example, a gold (Au) layer. The thickness of the second metal layer 52 is 300 nm or greater and 1000 nm or less. The third metal layer 53 enhances the adhesion between the first metal layer 51 and the second metal layer 52. The third metal layer 53 is, for example, a titanium (Ti) layer. The thickness of the third metal layer 53 is 2 nm or greater and 20 nm or less.

Next, a method for manufacturing the high electron mobility transistor 100 according to the first embodiment will be described. FIG. 2 through 4 are cross-sectional views illustrating a method for manufacturing the high electron mobility transistor 100 according to the first embodiment.

First, as illustrated in FIG. 2, the buffer layer 122, the channel layer 124, the barrier layer 126, and the cap layer 128 are formed on the substrate 110. The buffer layer 122, the channel layer 124, the barrier layer 126, and the cap layer 128 can be formed by, for example, a metal organic chemical vapor deposition (MOCVD) method. Next, the insulating film 130 is formed on the cap layer 128. The insulating film 130 can be formed by, for example, a CVD method.

Next, the opening 130S and the opening 130D are formed in the insulating film 130, and the recess 140S and the recess 140D are formed in the cap layer 128, the barrier layer 126, and a part of the channel layer 124. The opening 130S and the opening 130D can be formed by reactive ion etching (RIE) using a reactive gas containing fluoride (F), for example. The recess 140S and the recess 140D can be formed by RIE using a reactive gas containing, for example, chloride (Cl). Next, the regrowth layer 142S is formed in the recess 140S and the opening 130S, and the regrowth layer 142D is formed in the recess 140D and the opening 130D. The regrowth layers 142S and 142D can be formed by, for example, MOCVD, molecular beam epitaxy (MBE), or sputtering. In this way, the semiconductor stacked body 120 is obtained.

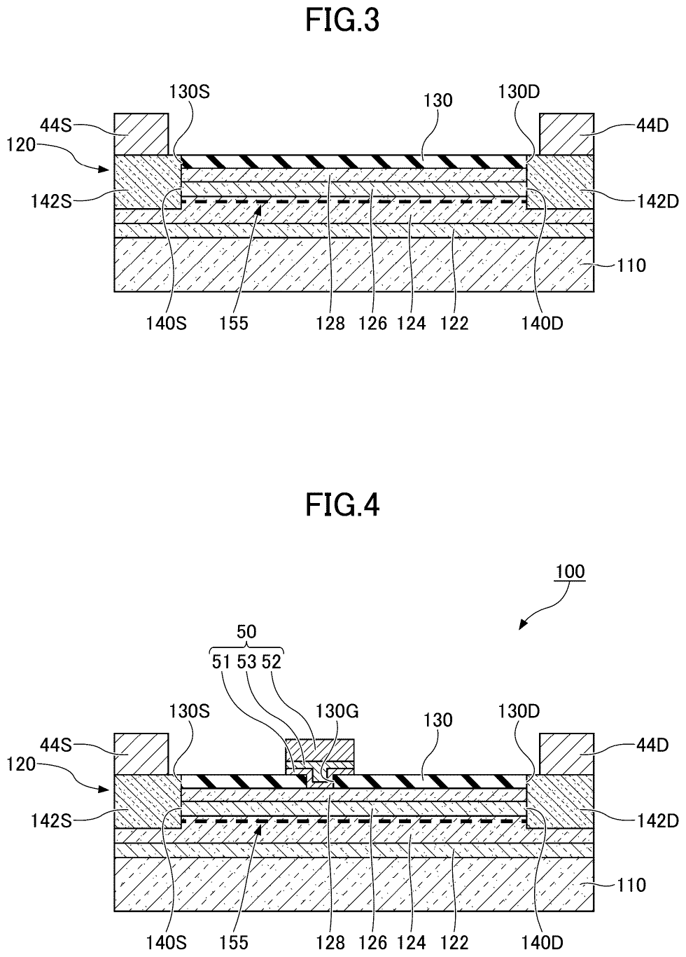

Next, as illustrated in FIG. 3, the source electrode 44S is formed on the regrowth layer 142S, and the drain electrode 44D is formed on the regrowth layer 142D. The source electrode 44S and the drain electrode 44D can be formed by, for example, vapor deposition and lift-off.

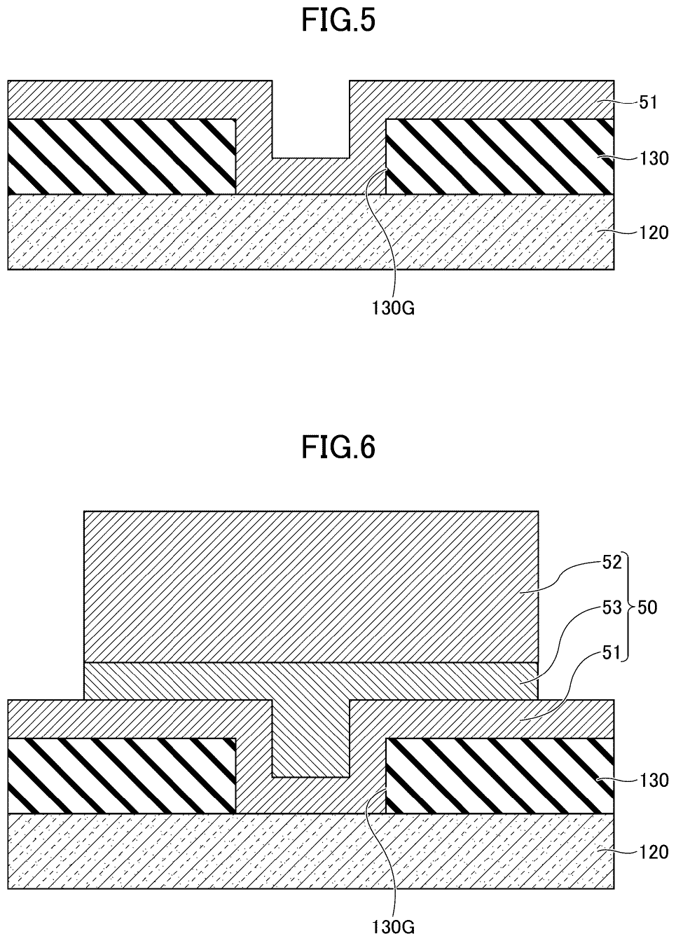

Next, as illustrated in FIG. 4, the opening 130G is formed in the insulating film 130. The opening 130G can be formed by RIE using a reactive gas containing fluoride (F), for example. Next, the gate electrode 50 is formed on the insulating film 130 so as to be in Schottky contact with the semiconductor stacked body 120 through the opening 130G.

Hereinafter, a method of forming the gate electrode 50 will be described in detail. FIGS. 5 through 7 are cross-sectional views illustrating the method of forming the gate electrode 50.

First, as illustrated in FIG. 5, the first metal layer 51 is formed on the insulating film 130, on the inner wall surface of the opening 130G, and on the portion of the semiconductor stacked body 120 exposed from the opening 130G by an atomic layer deposition (ALD) method. In the case where a Co layer is formed as the first metal layer 51, for example, bis(diisopropylbutanamidinate) cobalt is supplied as a source material of Co into an ALD furnace. At least one selected from the group consisting of hydrogen gas (H₂) and ammonia gas (NH₃) is supplied into the ALD furnace to decompose the source material of Co. Nitrogen gas (N₂) or argon gas (Ar), which are an inert gas, may be used as a carrier gas.

In forming the first metal layer 51, as illustrated in FIG. 8, for example, the temperature in the ALD furnace is increased from room temperature to 200° C., and the first metal layer 51 is formed at 200° C. Then, after the first metal layer 51 is formed, the temperature in the ALD furnace is decreased to room temperature. FIG. 8 is a diagram illustrating an example of a change in temperature when the gate electrode 50 is formed.

Next, as illustrated in FIG. 6, the second metal layer 52 and the third metal layer 53 are formed on the first metal layer 51. The second metal layer 52 and the third metal layer 53 can be formed by, for example, vapor deposition and lift-off.

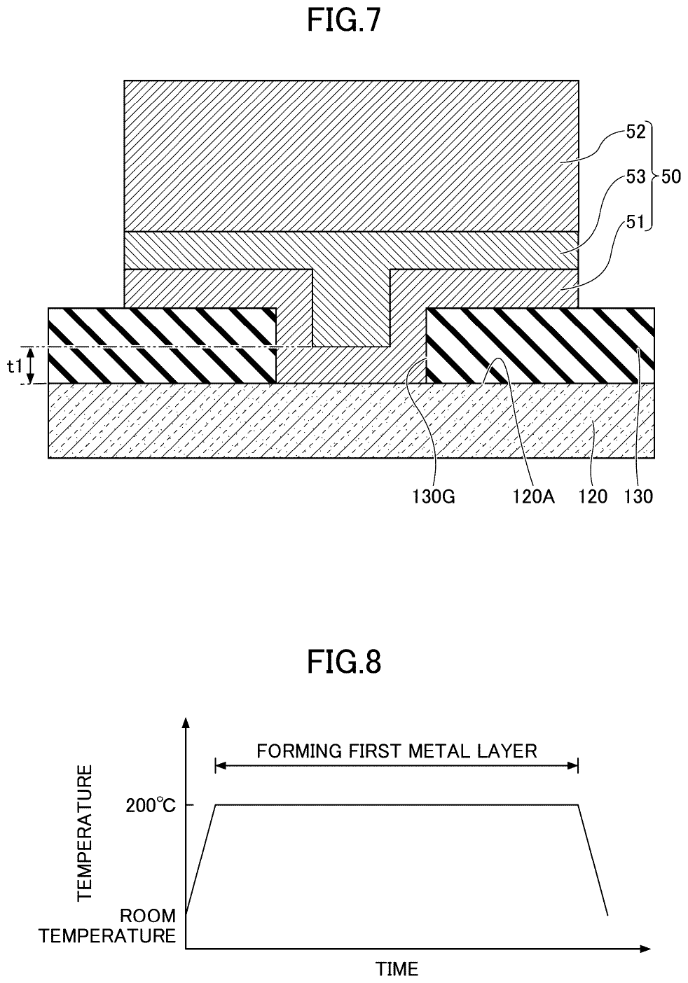

Next, as illustrated in FIG. 7, the portion of the first metal layer 51 exposed from the second metal layer 52 and the third metal layer 53 is removed by etching. This etching is, for example, wet etching. This etching may be RIE. Next, annealing is performed in a nitrogen gas (N₂) atmosphere at a temperature of 350° C. or greater and 450° C. or less for ten minutes or more and fifty minutes or less. As a result, the gate electrode 50 including the first metal layer 51, the second metal layer 52, and the third metal layer 53 is formed. This annealing may be performed before the etching of the portion of the first metal layer 51 exposed from the second metal layer 52 and the third metal layer 53.

In this way, the high electron mobility transistor 100 according to the first embodiment can be manufactured.

In the high electron mobility transistor 100 according to the first embodiment, the gate electrode 50 includes a Co layer in an amorphous state as the first metal layer 51. The amorphous Co layer can make gate leakage difficult to occur. Therefore, according to the first embodiment, gate leakage can be reduced.

The first metal layer 51 may include an amorphous ruthenium (Ru) layer instead of the amorphous Co layer, or may include an amorphous Co layer and an amorphous Ru layer. In the case where an amorphous Ru layer is formed by the ALD method, for example, bis(diisopropylbutanamidinate) ruthenium can be used as a source material of Ru.

In the case where the first metal layer 51 contains hydrogen, carbon, nitrogen, and oxygen, the state of the first metal layer 51 can be easily made amorphous. The ratio of hydrogen (H) atoms, carbon (C) atoms, nitrogen (N) atoms, and oxygen (O) atoms in the first metal layer 51 is, for example, 2 atom % or greater and 25 atom % or less. The ratio of each of H atoms, C atoms, N atoms, and O atoms can be measured by secondary ion mass spectrometry (SIMS). The H atoms and the N atoms are derived from the source material of the first metal layer 51 and the carrier gas. The C atoms and the O atoms are derived from the source material of the first metal layer 51.

The thickness of the first metal layer 51 is 3 nm or greater and 50 nm or less, as described earlier. If the thickness of the first metal layer 51 is less than 3 nm, it may be difficult to reduce gate leakage. If the thickness of the first metal layer 51 is greater than 50 nm, the electric resistance of the gate electrode 50 may become too high. The thickness of the first metal layer 51 may be 5 nm or greater and 30 nm or less, or 7 nm or greater and 20 nm or less.

The thickness of the first metal layer 51 can be measured using a transmission electron microscope (TEM) or a scanning transmission electron microscope (STEM). In the present disclosure, the width of the first metal layer 51 is a minimum dimension t1 along the vertical axis to the surface 120A of the semiconductor stacked body 120 inside the opening 130G, as illustrated in FIG. 7.

The gate electrode 50 includes the second metal layer 52, and the electrical resistance of the second metal layer 52 is lower than the electrical resistance of the first metal layer 51, thereby the electrical resistance of the gate electrode 50 can be suppressed to be low. The second metal layer 52 is not limited to an Au layer. The second metal layer 52 may contain at least one selected from the group consisting of gold, copper (Cu), and aluminum (Al).

The gate electrode 50 includes the third metal layer 53 between the first metal layer 51 and the second metal layer 52, and thus good adhesion is obtained between the first metal layer 51 and the second metal layer 52. In the case where the third metal layer 53 contains titanium, good adhesion can be easily obtained.

Since the semiconductor stacked body 120 includes the channel layer 124 and the barrier layer 126 between the channel layer 124 and the gate electrode 50, the channel layer 124 and the barrier layer 126 can be easily grown, and the channel layer 124 and the barrier layer 126 can easily have excellent crystallinity. The semiconductor stacked body 120 may include the cap layer 128, or does not need to include the cap layer 128. For example, in the case where the semiconductor stacked body 120 includes the cap layer 128, the gate electrode 50 is in direct contact with the cap layer 128; in the case where the semiconductor stacked body 120 does not include the cap layer 128 on the other hand, the gate electrode 50 is in direct contact with the barrier layer 126. In either case, gate leakage can be reduced. In the case where the semiconductor stacked body 120 includes the cap layer 128, the cap layer 128 also can easily have excellent crystallinity. Furthermore, electron traps can be easily reduced with this configuration.

The insulating film 130 is formed, and the gate electrode 50 is in Schottky contact with the semiconductor stacked body 120 through the opening 130G. Therefore, the semiconductor stacked body 120 can be protected by the insulating film 130.

Since the Co layer is formed as the first metal layer 51 by the ALD method, the first metal layer 51 can be easily made amorphous. Since the source material of the first metal layer 51 includes at least one selected from the group consisting of bis(diisopropylbutanamidinate) cobalt and bis(diisopropylbutaneamidinate) ruthenium, the first metal layer 51 in an amorphous state can be easily formed. Furthermore, since at least one selected from the group consisting of hydrogen gas (H₂) and ammonia gas (NH₃) is supplied into the ALD furnace together with the source material when the first metal layer 51 is formed, the source material can be easily decomposed and, in turn, particularly the first metal layer in an amorphous state can be easily formed. As long as either one of hydrogen gas or ammonia gas is supplied to the ALD furnace together with the source material, the other of hydrogen gas or ammonia gas does not need to be supplied. The source material can be decomposed as long as at least one of hydrogen gas or ammonia gas is supplied.

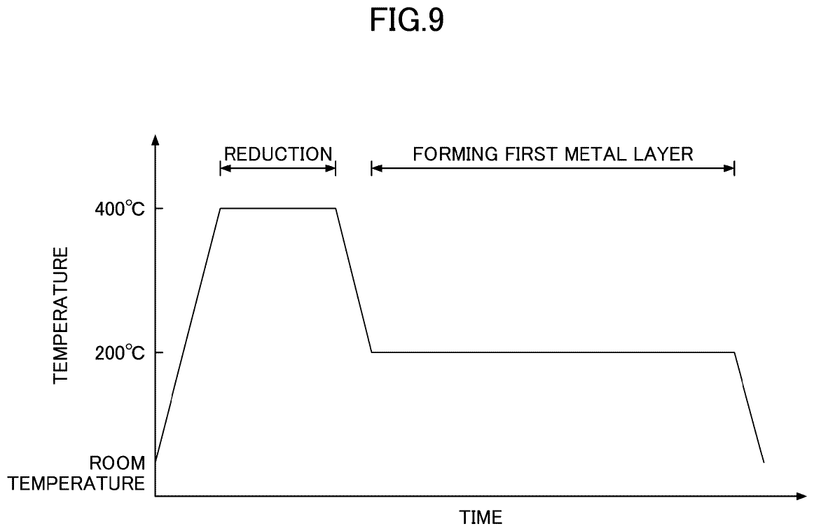

In the formation of the gate electrode 50, as illustrated in FIG. 9, a reduction process is performed at a first temperature at which a natural oxide film on the surface of the semiconductor stacked body 120 is decomposed before the formation of the first metal layer 51, and good Schottky characteristics are thereby obtained between the gate electrode 50 and the semiconductor stacked body 120. For example, a high Schottky barrier is obtained, a threshold voltage of the high electron mobility transistor 100 is increased, and a voltage applied to the gate electrode 50 can be increased. For example, the natural oxide film is a gallium oxide (Ga₂O₃) film, and the first temperature is 400° C. or greater and 500° C. or less. The first metal layer 51 is formed at a second temperature lower than the first temperature, for example, 150° C. or greater and 250° C. or less. FIG. 9 is a diagram illustrating another example of a change in temperature when the gate electrode 50 is formed.

For example, hydrogen gas (H₂) and ammonia gas (NH₃) are used for the reduction process. In this case, oxygen atoms are removed from the natural oxide film by hydrogen gas, and nitrogen vacancies in the semiconductor stacked body 120 are filled with ammonia gas. In the reduction process, for example, the flow rate of H₂ gas is set to be 1 standard cubic centimeter (sccm) or more and 500 sccm or less, and the flow rate of NH₃ gas is set to be 1 sccm or more and 500 sccm or less.

In the case where the reduction process is performed, the reduction process and the formation of the first metal layer 51 are performed in the same furnace without being opened to the atmosphere, that is, the process is continuously performed in situ, and particularly excellent cleanliness is thereby obtained on the surface of the semiconductor stacked body 120. Therefore, more excellent Schottky characteristics can be easily obtained. The supply of hydrogen gas and ammonia gas can be continued from the reduction process to the formation of the first metal layer 51.

In the case where the reduction process is performed, the reduction process and the formation of the first metal layer 51 are performed in respective furnaces without being opened to the atmosphere, and the temperature in the furnace in which the reduction process is performed and the temperature in the furnace in which the first metal layer 51 is formed are thereby controlled independently of each other, and thus high throughput can be easily obtained.

### Second Embodiment

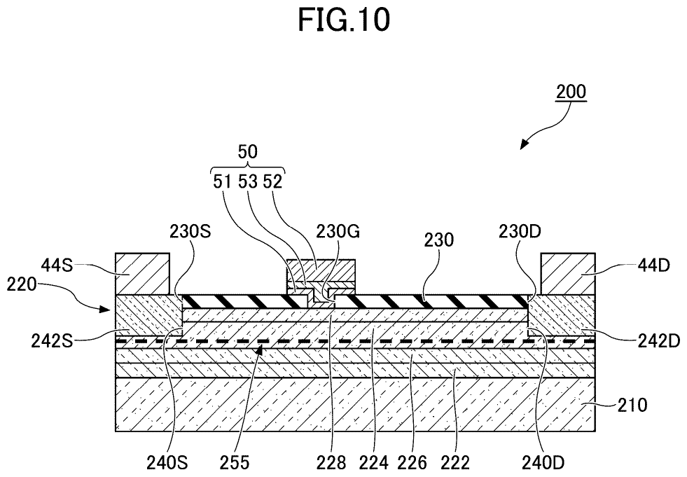

A second embodiment will be described. The second embodiment differs from the first embodiment mainly in the configuration of the substrate and the semiconductor stacked body. FIG. 10 is a cross-sectional view illustrating a high electron mobility transistor according to the second embodiment.

A high electron mobility transistor 200 according to the second embodiment includes a substrate 210, a semiconductor stacked body 220, an insulating film 230, a gate electrode 50, a source electrode 44S, and a drain electrode 44D, as illustrated in FIG. 10.

The substrate 210 is, for example, a substrate for growing a GaN-based semiconductor layer, and is, for example, a semi-insulating SiC substrate. In the case where the substrate 210 is a SiC substrate, the upper surface of the substrate 210 is a carbon (C) polar plane. In the case where the surface of the substrate 210 is a C polar plane, the semiconductor stacked body 220 is crystal-grown using a nitrogen (N) polar plane as a growth plane.

The semiconductor stacked body 220 includes a buffer layer 222, a barrier layer 226, a channel layer 224, a cap layer 228, a regrowth layer 242S, and a regrowth layer 242D.

The buffer layer 222 is on the substrate 210. The buffer layer 222 is, for example, an AlN layer. The buffer layer 222 may include an AlN layer and a GaN layer or an AlGaN layer on the AlN layer. The barrier layer 226 is on the buffer layer 222. The barrier layer 226 is, for example, an n-type AlGaN layer. The channel layer 224 is on the barrier layer 226. The channel layer 224 is, for example, an undoped GaN layer. A 2DEG 255 is present in the vicinity of the lower surface of the channel layer 224. The cap layer 228 is on the channel layer 224. The cap layer 228 is, for example, an AlN layer or an AlGaN layer.

A recess 240S for a source and a recess 240D for a drain are formed in the cap layer 228 and a part of the channel layer 224. The recess 240S and the recess 240D penetrate the cap layer 228 and enter the channel layer 224. The channel layer 224 is exposed from the recess 240S and the recess 240D.

The insulating film 230 is on the cap layer 228. The insulating film 230 is, for example, an SiN film. The thickness of the insulating film 230 is, for example, 1 nm or greater and 10 nm or less. An opening 230S for a source and an opening 230D for a drain are formed in the insulating film 230. The opening 230S connects to the recess 240S, and the opening 230D connects to the recess 240D.

The regrowth layer 242S is on the channel layer 224 in the recess 240S and the opening 230S. The regrowth layer 242D is on the channel layer 224 in the recess 240D and the opening 230D. The regrowth layers 242S and 242D are, for example, an n-type GaN layer. The electrical resistances of the regrowth layers 242S and 242D are lower than the electrical resistance of the channel layer 224.

The source electrode 44S is on the regrowth layer 242S, and the drain electrode 44D is on the regrowth layer 242D. The source electrode 44S is in direct contact with the regrowth layer 242S, and the drain electrode 44D is in direct contact with the regrowth layer 242D. The source electrode 44S is in ohmic contact with the regrowth layer 242S, and the drain electrode 44D is in ohmic contact with the regrowth layer 242D.

An opening 230G for a gate is formed in the insulating film 230. The opening 230G is between the opening 230S and the opening 230D. The gate electrode 50 is provided on the insulating film 230 and is in Schottky contact with the semiconductor stacked body 220 through the opening 230G.

Next, a method for manufacturing the high electron mobility transistor 200 according to the second embodiment will be described.

First, the buffer layer 222, the barrier layer 226, the channel layer 224, and the cap layer 228 are formed on the substrate 210. The buffer layer 222, the barrier layer 226, the channel layer 224, and the cap layer 228 can be formed by, for example, the MOCVD method. Next, the insulating film 230 is formed on the cap layer 228. The insulating film 230 can be formed by, for example, a CVD method.

Next, the opening 230S and the opening 230D are formed in the insulating film 230, and the recess 240S and the recess 240D are formed in the cap layer 228 and a part of the channel layer 224. The opening 230S and the opening 230D can be formed by RIE using a reactive gas containing fluoride (F), for example. The recess 240S and the recess 240D can be formed by RIE using a reactive gas containing, for example, chloride (Cl). Next, the regrowth layer 242S is formed in the recess 240S and the opening 230S, and the regrowth layer 242D is formed in the recess 240D and the opening 230D. The regrowth layers 242S and 242D can be formed by, for example, MOCVD, MBE, or sputtering. In this way, the semiconductor stacked body 220 is obtained.

Next, the source electrode 44S is formed on the regrowth layer 242S, and the drain electrode 44D is formed on the regrowth layer 242D. The source electrode 44S and the drain electrode 44D can be formed by the same method as that of the first embodiment.

Next, an opening 230G is formed in the insulating film 230. The opening 230G can be formed by RIE using a reactive gas containing fluoride (F), for example. Next, the gate electrode 50 is formed on the insulating film 230 so as to be in Schottky contact with the semiconductor stacked body 220 through the opening 230G. The gate electrode 50 can be formed by the same method as in the first embodiment.

In this way, the high electron mobility transistor 200 according to the second embodiment can be manufactured.

In the high electron mobility transistor 200 according to the second embodiment, the gate electrode 50 includes a Co layer in an amorphous state as the first metal layer 51. Therefore, as in the first embodiment, gate leakage can be reduced. In the second embodiment, the first metal layer 51 may include a ruthenium (Ru) layer in an amorphous state instead of the Co layer in an amorphous state.

Since the structure of the semiconductor stacked body 220 includes the barrier layer 226 and the channel layer 224 between the barrier layer 226 and the gate electrode 50, the contact resistance between the semiconductor stacked body 220 and the source electrode 44S and the drain electrode 44D can be easily suppressed to be low. The semiconductor stacked body 220 may include the cap layer 228, or does not need to include the cap layer 228. For example, in the case where the semiconductor stacked body 220 includes the cap layer 228, the gate electrode 50 is in direct contact with the cap layer 228; in the case where the semiconductor stacked body 220 does not include the cap layer 228 on the other hand, the gate electrode 50 is in direct contact with the channel layer 224. In either case, gate leakage can be reduced. In the case where the semiconductor stacked body 220 includes the cap layer 228, the cap layer 228 also can easily have excellent crystallinity. Furthermore, electron traps can be easily reduced with this configuration.

Next, various experiments conducted by the inventor of the present invention will be described.

### First Experiment

In the first experiment, three samples (samples No. 1, No. 2, and No. 3) were fabricated, and leakage current was measured in the case where a reverse voltage of −5 V was applied to the gate electrode. For each of the three samples, a drain current (I) was measured while a gate voltage (V) was changed to obtain an I-V curve, and a Schottky barrier and an ideality factor were calculated from the I-V curve.

In the formation of the semiconductor stacked body of sample No. 1, sample No. 2, and sample No. 3, a barrier layer was formed on a channel layer as in the first embodiment.

In the fabrication of sample No. 1, when a gate electrode was formed, vapor deposition and lift-off of a nickel (Ni) layer, a palladium (Pd) layer, and a gold (Au) layer were performed, and then annealing was performed. In this way, a gate electrode in which a Ni layer, a Pd layer, and an Au layer were stacked in this order was formed.

In the fabrication of sample No. 2, when forming the gate electrode, as in the first embodiment, the formation of the Co layer by the ALD method, vapor deposition and lift-off of the Ti layer and the Au layer were performed, and then etching and annealing of the Co layer were performed. In this way, a gate electrode in which a Co layer, a Ti layer, and an Au layer were stacked in this order was formed.

In the fabrication of sample No. 3, when forming the gate electrode, a reduction process is performed, and thereafter, as in the first embodiment, the formation of the Co layer by the ALD method, vapor deposition and lift-off of the Ti layer and the Au layer were performed, and then etching and annealing of the Co layer were performed. In this way, a gate electrode in which a Co layer, a Ti layer, and an Au layer were stacked in this order was formed.

Other conditions of samples No. 1, No. 2 and No. 3 are the same.

The leakage current, the Schottky barrier, and the ideality factor are shown in Table 1.

TABLE 1

| | | | Leakage | Schottky | |
|---|---|---|---|---|---|
| Sample | Gate | Reduction | current | barrier | Ideality |
| No. | electrode | process | (A/cm²) | (eV) | factor |
| 1 | Ni/Pd/Au | Not | 2 × 10⁻⁴ | 1.20 | 1.16 |
| | | performed | | | |
| 2 | Co/Ti/Au | Not | 7 × 10⁻⁵ | 1.00 | 1.60 |
| | | performed | | | |
| 3 | Co/Ti/Au | Performed | 9 × 10⁻⁶ | 1.26 | 1.10 |

As shown in Table 1, the leakage current was lower in sample No. 2 and sample No. 3 than in sample No. 1. In sample No. 3, the Schottky barrier was larger than that of sample No. 1, and the ideality factor was close to 1.00. In other words, in sample No. 3, better Schottky characteristics were obtained than in sample No. 1.

### Second Experiment

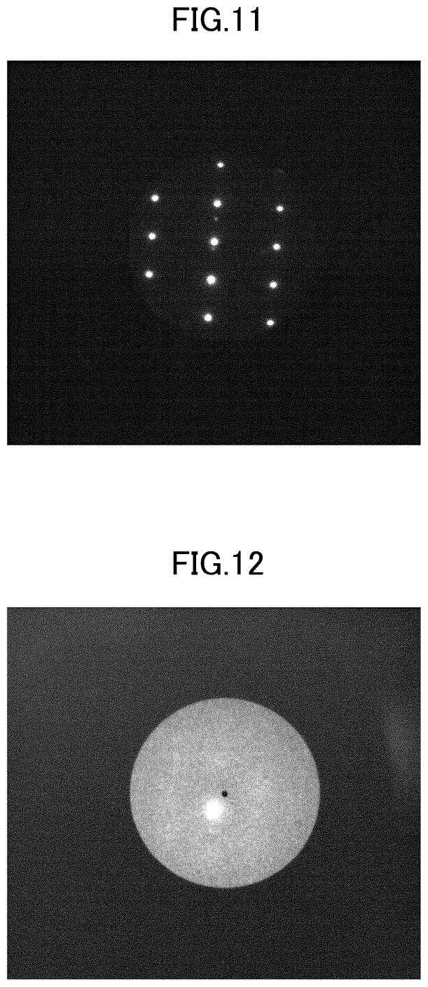

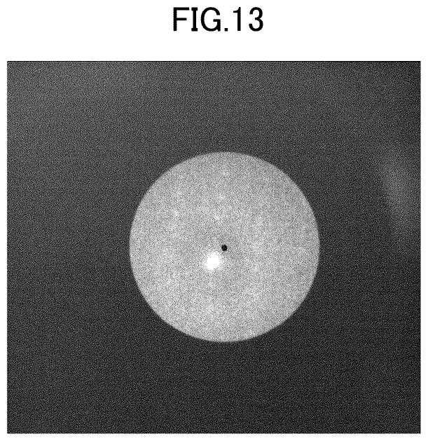

In the second experiment, the structures of the Ni layer in sample No. 1, the Co layer in sample No. 2, and the Co layer in sample No. 3 were analyzed by electron diffraction using a scanning transmission electron microscope (STEM). Electron diffraction images of the three samples are illustrated in FIGS. 11 to 13. FIG. 11 is an electron beam diffraction image of sample No. 1. FIG. 12 is an electron beam diffraction image of sample No. 2. FIG. 13 is an electron beam diffraction image of sample No. 3.

As illustrated in FIG. 11, the Ni layer in sample No. 1 was a single crystal. On the other hand, as illustrated in FIGS. 12 and 13, the Co layer in sample No. 2 and the Co layer in sample No. 3 were in an amorphous state.

Although the embodiments have been described in detail, the present disclosure is not limited to the specific embodiments, and various modifications and changes can be made within the scope described in the claims.

What is claimed is:

1. A high electron mobility transistor, comprising:
a substrate;
a semiconductor stacked body provided on the substrate; and
a gate electrode in Schottky contact with the semiconductor stacked body, the gate electrode including
a first metal layer in direct contact with the semiconductor stacked body; and
a second metal layer covering the first metal layer, wherein
the first metal layer contains at least one selected from the group consisting of cobalt in an amorphous state and ruthenium in an amorphous state.

2. The high electron mobility transistor according to claim 1, wherein
an electrical resistance of the second metal layer is lower than an electrical resistance of the first metal layer.

3. The high electron mobility transistor according to claim 1, wherein
the first metal layer contains a hydrogen atom, a carbon atom, a nitrogen atom, and an oxygen atom.

4. The high electron mobility transistor according to claim 1, wherein
the second metal layer contains at least one selected from the group consisting of gold, copper, and aluminum.

5. The high electron mobility transistor according to claim 1, wherein
a thickness of the first metal layer is 3 nm or greater and 50 nm or less.

6. The high electron mobility transistor according to claim 1, wherein
the gate electrode includes a third metal layer between the first metal layer and the second metal layer.

7. The high electron mobility transistor according to claim 6, wherein
the third metal layer contains titanium.

8. The high electron mobility transistor according to claim 1, wherein
the semiconductor stacked body includes
a channel layer; and
a barrier layer between the channel layer and the gate electrode, and
the gate electrode is in direct contact with the barrier layer.

9. The high electron mobility transistor according to claim 1, wherein
the semiconductor stacked body includes
a channel layer;
a barrier layer between the channel layer and the gate electrode; and
a cap layer between the barrier layer and the gate electrode, and
the gate electrode is in direct contact with the cap layer.

10. The high electron mobility transistor according to claim 1, wherein
the semiconductor stacked body includes
a barrier layer; and
a channel layer between the barrier layer and the gate electrode, and
the gate electrode is in direct contact with the channel layer.

11. The high electron mobility transistor according to claim 1, wherein
the semiconductor stacked body includes
a barrier layer;
a channel layer between the barrier layer and the gate electrode; and
a cap layer between the channel layer and the gate electrode, and
the gate electrode is in direct contact with the cap layer.

12. The high electron mobility transistor according to claim 1, further comprising:
an insulating film covering the semiconductor stacked body, wherein
an opening is formed in the insulating film, and
the gate electrode is in Schottky contact with the semiconductor stacked body through the opening.

13. A method of manufacturing a high electron mobility transistor, the method comprising:
forming a semiconductor stacked body on a substrate; and
forming a gate electrode in Schottky contact with the semiconductor stacked body, the forming of the gate electrode including
forming a first metal layer in direct contact with the semiconductor stacked body by atomic layer deposition; and
forming a second metal layer covering the first metal layer, wherein
the first metal layer contains at least one selected from the group consisting of cobalt in an amorphous state and ruthenium in an amorphous state.

14. The method for manufacturing a high electron mobility transistor according to claim 13, wherein
a source material of the first metal layer contains at least one selected from the group consisting of bis(diisopropylbutanamidinate) cobalt and bis(diisopropylbutaneamidinate) ruthenium.

15. The method for manufacturing a high electron mobility transistor according to claim 14, wherein
in the forming of the first metal layer, at least one selected from the group consisting of hydrogen gas and ammonia gas is supplied into a furnace together with the source material.

16. The method for manufacturing a high electron mobility transistor according to claim 13, wherein
the forming of the gate electrode includes performing, before the forming of the first metal layer, a reduction treatment at a first temperature at which a natural oxide film on a surface of the semiconductor stacked body is decomposed, and
the first metal layer is formed at a second temperature lower than the first temperature.

17. The method for manufacturing a high electron mobility transistor according to claim 16, wherein
the performing of the reduction treatment and the forming of the first metal layer are performed in a same furnace without being exposed to the atmosphere.

18. The method for manufacturing a high electron mobility transistor according to claim 16, wherein
the performing of the reduction treatment and the forming of the first metal layer are performed in respective furnaces without being exposed to the atmosphere.

19. The method for manufacturing a high electron mobility transistor according to claim 16, wherein
hydrogen gas and ammonia gas are used in the reduction treatment.
